(19) United States
(12) Patent Application Publication
(10) Pub. No.: US 2025/0373262 A1
(43) Pub. Date: Dec. 4, 2025

(54) ANALOG-TO-DIGITAL CONVERTER CIRCUIT

(71) Applicant: Nuvoton Technology Corporation, Hsinchu Science Park (TW)

(72) Inventors: Cheng-Feng SHIH, Taoyuan City (TW); Jui-Hsien FANG, Hsinchu Science Park (TW)

(21) Appl. No.: 19/207,993

(22) Filed: May 14, 2025

(30) Foreign Application Priority Data
Jun. 3, 2024 (TW) 113120444

(51) Int. Cl. H03M 3/00

(52) U.S. Cl. CPC H03M 3/496

(57) ABSTRACT

An analog-to-digital converter (ADC) circuit including a programmable gain amplifier (PGA), a buffer, a delta sigma ADC, and a bandwidth control circuit is provided. The PGA is configured to receive and amplify an input signal to generate an amplification signal. The buffer is configured to receive the amplification signal and output a corresponding buffered signal. The delta sigma ADC is configured to receive the amplification signal and the buffered signal, and output a corresponding digital signal. The bandwidth control circuit is configured to generate a first control signal and a second control signal, wherein the first control signal is output to the PGA to control the bandwidth of the PGA, and the second control signal is configured to enable or disable the buffer.

### CROSS REFERENCE TO RELATED APPLICATIONS

This Application claims priority of Taiwan Patent Application No. 113120444, filed on Jun. 3, 2024, the entirety of which is incorporated by reference herein.

### BACKGROUND OF THE INVENTION

### Field of the Invention

The present invention relates to an analog-to-digital converter circuit, and, in particular, to an analog-to-digital converter circuit with controllable bandwidth.

### Description of the Related Art

High resolution analog-to-digital converters (ADCs) have been generally used in analog or precision sensing applications in recent years, and further require high resolution ADCs with high speed. An amplifier, such as a closed loop amplifier, is generally added to the front end output of the ADC to amplify the input analog signal or other small-signals. However, the gain and bandwidth of the closed loop amplifier are substantially inversely proportional; that is, the higher the gain, the smaller the bandwidth will be. Thus, the upper bound of the sampling bandwidth of the high-speed ADC is further limited, causing the speed of the high-speed ADC to be reduced, or having large signal distortion.

Although adding other circuits with amplifiable bandwidth between a closed loop amplifier and a high-speed ADC can solve the problem of insufficient sampling bandwidth of the high-speed ADC, it will increase circuit noise and cause distortion. Therefore, a solution is needed to solve the above problem.

### BRIEF SUMMARY OF THE INVENTION

An analog-to-digital converter circuit is provided, comprising a programmable gain amplifier, a buffer, a delta sigma analog-to-digital converter, and a bandwidth control circuit. The programmable gain amplifier is configured to receive and amplify an input signal to generate an amplified signal. The buffer is configured to receive the amplified signal and output a buffered signal correspondingly. The delta sigma analog-to-digital converter is configured to receive the amplified signal or the buffered signal, and output a digital signal correspondingly. The bandwidth control circuit is configured to generate a first control signal and a second control signal, wherein the first control signal is output to the programmable gain amplifier to control the bandwidth of the programmable gain amplifier, and the second control signal is configured to enable or disable the buffer.

In accordance with some embodiments of the present invention, the analog-to- digital converter circuit further comprising a switch, having a first end and a second end. The first end is coupled to an input of the buffer, and the second end is coupled to an output of the buffer, wherein the bandwidth control circuit generates a third control signal to turn on or turn off the switch.

In accordance with some embodiments of the present invention, when the bandwidth of the programmable gain amplifier is not less than the input bandwidth required by the delta sigma analog-to-digital converter, the bandwidth control circuit outputs the second control signal to disable the buffer and the third control signal to turn on the switch. This causes the programmable gain amplifier outputs the amplified signal to the delta sigma analog-to-digital converter through the switch which is turned on.

In accordance with some embodiments of the present invention, when the bandwidth of the programmable gain amplifier is less than the input bandwidth required by the delta sigma analog-to-digital converter, the bandwidth control circuit outputs the second control signal to enable the buffer and the third control signal to turn off the switch. This causes the programmable gain amplifier outputs the amplified signal to the buffer, and the buffer outputs the buffered signal to the delta sigma analog-to-digital converter.

### BRIEF DESCRIPTION OF THE DRAWINGS

The present invention can be more fully understood by reading the subsequent detailed description and examples with references made to the accompanying drawings, wherein:

FIGS. 1A and 1B show examples of a delta sigma analog-to-digital converter, in accordance with embodiments of the present invention;

FIG. 2 is a schematic diagram of an analog-to-digital converter circuit, in accordance with embodiments of the present invention;

FIGS. 3A and 3B show several examples of some programmable gain amplifiers, in accordance with embodiments of the present invention; and

FIG. 4 shows an example of a buffer, in accordance with embodiments of the present invention.

### DETAILED DESCRIPTION OF THE INVENTION

The following description is made for the purpose of illustrating the general principles of the invention and should not be taken in a limiting sense. The scope of the invention is best determined by reference to the appended claims.

To better understand the above and other purposes, features, and advantages of the present invention, the preferred embodiments with accompanying figures are listed and described in detail below.

Some embodiments are described below so that those ordinarily skilled in the art can readily understand the embodiments of the present invention. However, these embodiments are merely examples and not for limiting the embodiments of the present invention. It should be understood, those skilled in the art may modify the embodiments described below according to their needs; for example, they may change the orders of the processes, and/or include more or fewer steps than described herein without departing from the spirit and scope of the embodiments of the present invention.

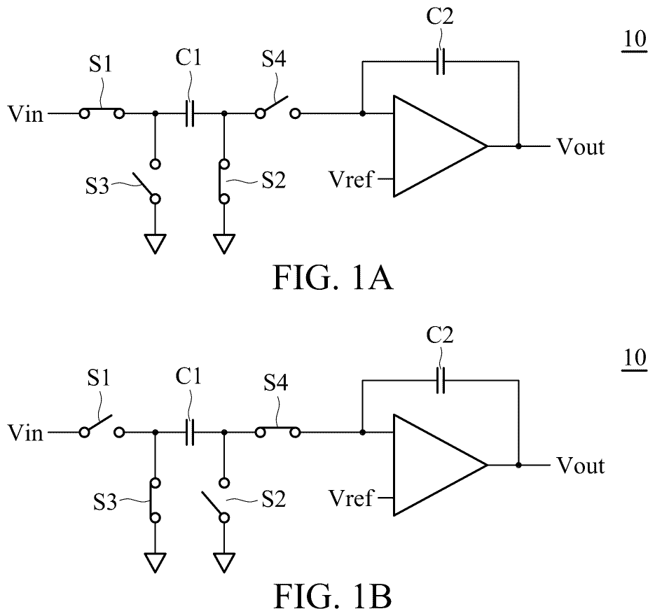

The delta sigma analog-to-digital converter (delta sigma ADC) is a widely used high resolution ADC, and as demands increase for the delta sigma ADCs with high output speed, high-speed ADCs are becoming more important. FIGS. 1A and 1B illustrate examples of a delta sigma ADC 10 during the first half and the last half of the sampling period, respectively. The delta sigma ADC 10 includes switches S1-S4, capacitors C1 and C2, and an operational amplifier.

As shown in FIG. 1A, during the first half of the sampling period, switches S1 and S2 are turned on, and switches S3 and S4 are turned off such that an input signal Vin charges the capacitor C1. Then, as shown in FIG. 1B, during the last half of the sampling period, the switches S1 and S2 are turned off, and the switches S3 and S4 are turned on. This causes that the voltage on the capacitor C1 is transferred to the capacitor C2 to obtain an output signal Vout (i.e., the result of the current sampling period) through the operational amplifier and a reference signal Vref. Due to the characteristics of oversampling, the delta sigma ADC 10 requires the input with high bandwidth. If the bandwidth of the input signal Vin is insufficient, the time for the delta sigma ADC 10 to sample is insufficient, resulting in increased noise or distortion of the input signal Vin. To solve the problem above, embodiments of the present invention provides an ADC circuit with controllable input signal bandwidth.

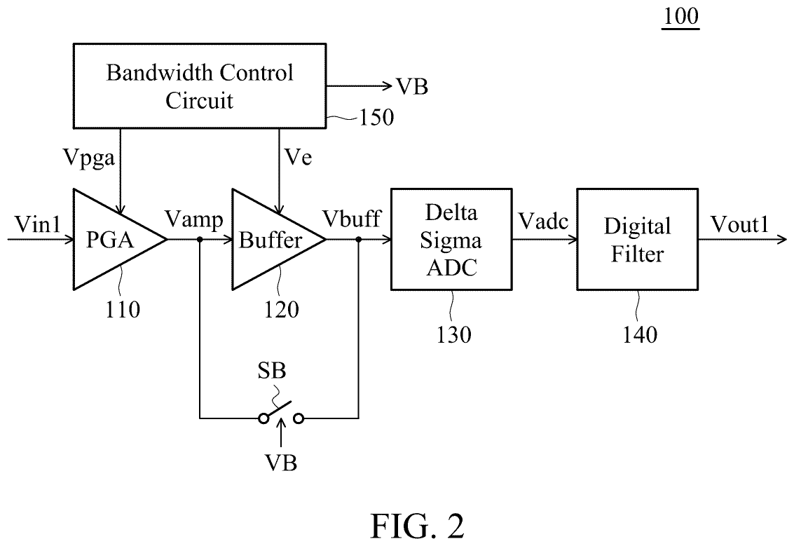

FIG. 2 is an ADC circuit 100, illustrated in accordance with embodiments of the present invention, includes a programmable gain amplifier (PGA) 110, a buffer 120, a delta sigma ADC 130, a digital filter 140, and a bandwidth control circuit 150. The PGA 110 receives an input signal Vin1 (e.g., an analog signal or a precision sensing signal), performs amplification on the input signal Vin1 with a default magnification to generate an amplified signal Vamp, and outputs it to the buffer 120. The buffer 120 receives the amplified signal Vamp, and outputs a corresponding buffered signal Vbuff to the delta sigma ADC 130. The sampling period operation of the delta sigma ADC 130 is similar to that in FIGS. 1A and 1B and is not described here again. Then, the delta sigma ADC 130 performs the transformation on the buffered signal Vbuff, and outputs a corresponding digital signal Vadc to the digital filter 140. The digital filter 140 then performs filtering on the digital signal Vadc to obtain an output signal Vout1.

The bandwidth control circuit 150 can generate the control signals Vpga, Ve, and VB to control the PGA 110, the buffer 120 and a switch SB, respectively. Based on the default gain of the PGA 110 (or the gain set by the user for the PGA 110), the bandwidth control circuit 150 can control the PGA 110 through controlling the control signal Vpga such that the PGA 110 has optimized gain, bandwidth and other parameters. For example, the bandwidth control circuit 150 changes the current of the PGA 110 (e.g., doubles the original) through controlling the control signal Vpga to increase the bandwidth. For example, when the gain of the PGA 110 is preset to 32 times or exceeds 32 times (e.g., 128 times) such that the bandwidth of the PGA 110 is excessively reduced due to the over-high gain, the bandwidth control circuit 150 will output the control signal Vpga to increase the current of the PGA 110 for increasing the bandwidth. This prevents the output bandwidth of the PGA 110 from being smaller than the input bandwidth required by the buffer 120. Then, when the gain and bandwidth of the PGA 110 is determined, the bandwidth control circuit 150 will automatically generate the corresponding control signals Ve and VB, based on the gain and bandwidth of the PGA 110. The control signal Ve is configured to enable or disable the buffer 120, and the control signal VB is configured to turn on or turn off the switch SB. Therefore, the bandwidth control circuit 150 can determine whether to skip the suffer 120 during the signal processing process through the control signals Ve and VB.

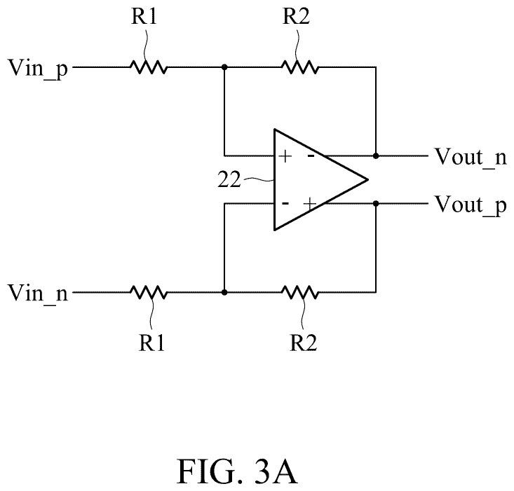

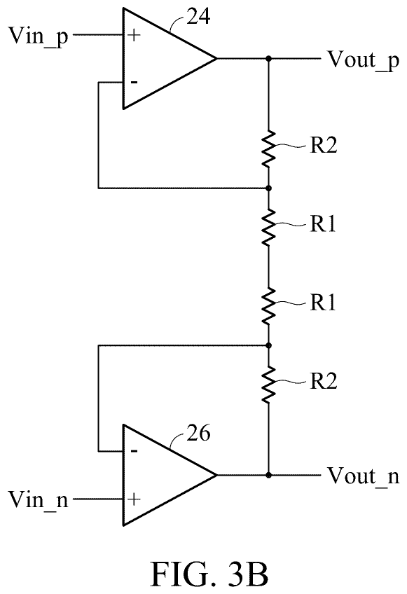

FIGS. 3A and 3B are several examples of the achievable PGA 110, described in accordance with embodiments of the present invention. Note that any suitable circuit for implementing the PGA may be used to implement the PGA 110, and the present invention is not limited herein. The first type double-ended differential amplifier shown in FIG. 3A has a pair of differential inputs, a pair of differential outputs, the resistors R1 and R2, and an operational amplifier 22. The above differential inputs are configured to receive a positive input signal Vin_p and a negative input signal Vin_n and the above differential outputs are configured to output a positive output signal Vout_p and a negative output signal Vout_n. The differential input signal of the first type double-ended differential amplifier and the input of the operational amplifier are separated by the resistor R1. Thus, it is suitable for applications where the positive input signal Vin_p and negative input signal Vin_n have a certain level (i.e., the voltage level that can overcome the resistance of the resistor R1). Suppose that the open loop gain is A, the closed loop gain is G0, and the open loop bandwidth is Ft, the following relationship can be derived:

$$\begin{matrix}G 0 = \frac{Vout\_p - Vout\_n}{Vin\_p - Vin\_n} = - \frac{R 2}{R 1} \times \frac{A}{1 + A} ≅ - \frac{R 2}{R 1} \\ the closed loop bandwidth = \frac{Ft}{G 0}\end{matrix}$$

The second type double-ended differential amplifier shown in FIG. 3B has a pair of differential inputs, a pair of differential outputs, the resistors R1 and R2, and the operational amplifiers 24 and 26. The second type double-ended differential amplifier uses the operational amplifier 24 to receive the positive input signal Vin_p and outputs the positive output signal Vout_p. The second type double-ended differential amplifier uses operational amplifier 26 to receive the negative input signal Vin_n and outputs the negative output signal Vout_n. Since the second type double-ended differential amplifier receives the input signal directly through operational amplifiers 24 and 26, it is suitable for applications receiving input signals with a smaller voltage level (e.g., the sensor signal). Suppose that the open loop gain is A, the closed loop gain is G0, and the open loop bandwidth is Ft, the following relationship can be derived:

$$\begin{matrix}G 0 = \frac{Vout\_p - Vout\_n}{Vin\_p - Vin\_n} = - \frac{R 2}{R 1} \times \frac{A}{1 + A} ≅ - \frac{R 2}{R 1} \\ the closed loop bandwidth = \frac{Ft}{G 0}\end{matrix}$$

As described above, from the relationship of the first type double-ended differential amplifier and the second type double-ended differential amplifier, it can be understood that the closed loop gain G0 is affected by resistors R1 and R2, while the closed loop bandwidth is affected by the closed loop gain G0 (e.g., inversely proportional to the closed loop gain). Therefore, when the closed loop gain G0 increases, the closed loop bandwidth will decrease. When the closed loop gain G0 becomes too large (e.g., 64 times or 128 times), the closed loop bandwidth may be reduced to be insufficient to support oversampling performed by the delta sigma ADC 130 (i.e., the closed loop bandwidth is smaller than the input bandwidth of the delta sigma ADC 130). At this time, the buffer 120 can be added between the PGA 110 and the delta sigma ADC 130 to ensure that the input bandwidth of the delta sigma ADC 130 is sufficient for performing normal sampling.

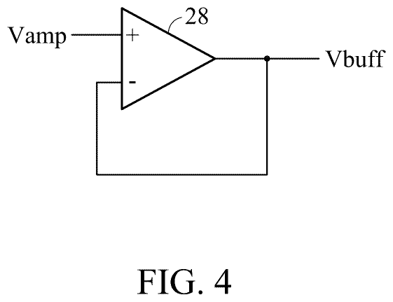

FIG. 4 is an example of the achievable buffer 120, described in accordance with embodiments of the present invention. Note that any suitable circuit for implementing the buffer may be used to implement the buffer 120, and the present invention is not limited herein. The buffer shown in FIG. 4 has an operational amplifier 28 that feeds the output back to the negative input (i.e., connected in the form of a unit gain buffer). This buffer also receives amplified signal Vamp from the positive input of the operational amplifier 28, and then outputs the buffered signal Vbuff to the delta sigma ADC 130 from the output of the operational amplifier 28. Suppose that the open loop gain is A, the closed loop gain is G0, and the open loop bandwidth is Ft, the following relationship can be derived:

$$\begin{matrix}G 0 = \frac{Vbuff}{Vamp} = \frac{A}{1 + A} ≅ 1 \\ the closed loop bandwidth = \frac{Ft}{G 0} ≅ Ft\end{matrix}$$

In addition, if the resistances of resistors R1 and R2 in the first type double- ended differential amplifier in FIG. 3A are set equal, the relationship can be modified as follows:

$$\begin{matrix}G 0 = \frac{Vout\_p - Vout\_n}{Vin\_p - Vin\_n} = - \frac{R 2}{R 1} \times \frac{A}{1 + A} ≅ - \frac{A}{1 + A} = - 1 \\ the closed loop bandwidth = \vert \frac{Ft}{G 0} \vert ≅ Ft\end{matrix}$$

That is, the first type double-ended differential amplifier in FIG. 3A also can achieve the effect of a unit gain buffer after appropriately adjusting the resistance relationship of resistors R1 and R2.

As described above, from the relationship of the buffer shown in FIG. 4, it can be understood that when it is connected as a unit gain buffer, the closed loop bandwidth equals the open loop bandwidth Ft since the closed loop gain G0 is 1 (or nearly equal to 1). Therefore, when the buffer 120 is added between the PGA 110 and the delta sigma ADC 130, the input bandwidth of the delta sigma ADC 130 is the output bandwidth of the buffer 120, rather than the closed loop bandwidth of the PGA 110, which varies with the gain. That is, the buffer 120 separates the PGA 110 and the delta sigma ADC 130, and provides the output bandwidth of the buffer 120 itself as the input bandwidth of the delta sigma ADC 130. In this way, the user can set the buffer 120 with sufficient bandwidth (e.g., not smaller than the input bandwidth of the delta sigma ADC 130) based on the requirements of the delta sigma ADC 130. Furthermore, since the buffer 120 is connected as a unit gain buffer, it will not cause a significant impact on the high gain provided by the PGA 110.

Please refer to FIG. 2 again, when the PGA 110 has a low gain (e.g., a gain smaller than 8), the impact on the closed loop bandwidth is also low. Therefore, after the bandwidth control circuit 150 defines the gain of the PGA 110, it determines that the amplified signal Vamp can be directly output to the delta sigma ADC 130, and then it will output the control signal VB to turn on the switch SB and the control signal Ve to disable the buffer 120. Since both ends of the switch SB are coupled to the input and output of the buffer 120 respectively, the buffer 120 is disabled and the switch SB is turned on such that the amplified signal Vamp is output to the delta sigma ADC 130 directly through the turned on switch SB without passing through the buffer 120. These operations can not only reduce the power consumption of enabling the buffer 120, but also eliminate the noise caused by the buffer 120, improving the noise performance of the digital signal Vadc output by the delta sigma ADC 130.

Conversely, when the PGA 110 has a high gain (e.g., a gain higher than or equals to 8), the impact on the closed loop bandwidth is also high. Therefore, after the bandwidth control circuit 150 defines the gain of the PGA 110, it determines that the amplified signal Vamp should pass through the buffer 120 before being output to the delta sigma ADC 130. The bandwidth control circuit 150 outputs the control signal VB to turn off the switch SB and the control signal Ve to enable the buffer 120, such that the amplified signal Vamp passes through the buffer 120 to generate the buffered signal Vbuff, and then output to the delta sigma ADC 130. For the delta sigma ADC 130, the input bandwidth at this time is the output bandwidth of the buffer 120. Thus, the bandwidth control circuit 150 ensures the required input bandwidth of the delta sigma ADC 130, thereby ensuring that delta sigma ADC 130 samples successfully when the PGA 110 has high gain.

For example, when the delta sigma ADC 130 has a sampling bandwidth (e.g., 1 MHz), the input signal (e.g., the input signal Vin1 or the buffered signal Vbuff) is typically required to have at least 10 times (e.g., 10 MHz) the input bandwidth. If the PGA 110 at this time has a high gain (e.g., a gain is not smaller than 8), when the amplified signal Vamp is directly input to the delta sigma ADC 130, the input bandwidth may be smaller than 10 MHz due to the over-high gain. This causes that the sampling time for the delta sigma ADC 130 is insufficient, resulting in the increased noise or distortion of the digital signal Vadc. At this time, the bandwidth control circuit 150 outputs the control signals Ve and VB to enable the buffer 120 as well as turn off the switch SB such that the delta sigma ADC 130 converts from directly receiving the amplified signal Vamp to receiving the buffered signal Vbuff. The user only needs to adjust the output bandwidth of the buffer 120 to be not smaller than the input bandwidth of the delta sigma ADC 130 (e.g., at least 10 MHz in this example). This ensures that the digital signal Vadc output by the delta sigma ADC 130 will not be distorted due to insufficient sampling time, even with the high gain of the PGA 110.

Conversely, if the PGA 110 has low gain (e.g., a gain of 1 or 2), the PGA 110 can provide a bandwidth that is not smaller than the input bandwidth required by the delta sigma ADC 130 (e.g., at least 10 MHz in this example). At this time, the bandwidth control circuit 150 outputs control signals Ve and VB to disable the buffer 120 and turn on the switch SB so that the amplified signal Vamp is directly output to the delta sigma ADC 130 through the turned on switch SB. In this way, the power consumption and noise of the buffer 120 can be reduced while the delta sigma ADC 130 can operate normally.

Table 1 below shows the described examples of the PGA 110, the buffer 120 and parameters such as current, gain, bandwidth etc. controlled by the bandwidth control circuit 150, in accordance with the present invention. Here, Ft_PGA is the closed loop bandwidth of the PGA 110, I is the bias current of the PGA 110 at unit gain, G0 is a closed loop gain of the PGA 110, and Ft_Buffer is the bandwidth of the buffer 120.

TABLE 1

| | | | Input signal |
|---|---|---|---|
| Gain of | Bias current | State of | bandwidth of the |
| the PGA | of the PGA | the buffer | delta sigma ADC |
| 1 · G0 | 1 · I | Disable and | Ft_PGA |
| | | skip | |
| 2 · G0 | 1 · I | Disable and | Ft_PGA/2 |
| | | skip | |
| 4 · G0 | 1 · I | Disable and | Ft_PGA/4 |
| | | skip | |
| 8 · G0 | 1 · I | Enable | Ft_Buffer |
| 16 · G0 | 1 · I | Enable | Ft_Buffer |
| 32 · G0 | 2 · I | Enable | Ft_Buffer |
| 64 · G0 | 2 · I | Enable | Ft_Buffer |
| 128 · G0 | 2 · I | Enable | Ft_Buffer |

Generally, the bandwidth of the PGA is related to the bias current, and the larger the bias current, the larger the bandwidth of the PGA. For example, as described in table 1, when the gain of the PGA 110 reaches or exceeds 32 times the original, the bandwidth control circuit 150 can adjust the magnitude of the bias current (e.g., adjusting it to twice the original) of the PGA 110 through the control signal Vpga to control the bandwidth of the PGA 110. Suppose that the closed loop gain is G0, the open loop bandwidth is Ft, the bias current I and the closed loop bandwidth of the PGA 110 can be expressed by the following relationship:

$$\begin{matrix}When the bias current = I , the open loop bandwidth = Ft , the closed loop bandwidth = \frac{Ft}{G 0} \\ When the bias current = 2 \cdot I , the open loop bandwidth = 2 \cdot Ft , the closed bandwidth = 2 \cdot \frac{Ft}{G 0}\end{matrix}$$

That is, if the bias current is adjusted to twice the original, the open loop bandwidth will also double, and the closed loop bandwidth also becomes twice the original without affecting the closed loop gain G0 to achieve the purpose of increasing the bandwidth of the PGA 110. However, note that although adjusting bias current I can increase bandwidth without affecting the gain of the PGA 110, increasing bias current I will also raise power consumption. Therefore, moderately adjusting the magnitude of bias current I can achieve the increasing of the bandwidth while maintaining power consumption similar to its level before the adjustment of the bias current I.

Furthermore, as described in table 1, when the PGA 110 has a low gain (e.g., gains of 1, 2, or 4), the amplified signal Vamp received by the delta sigma ADC 130 has a bandwidth that corresponds to the gain multiple of the PGA 110 since the buffer 120 is disabled. For example, if the gain of the PGA 110 is 2, the bandwidth of the amplified signal Vamp is Ft_PGA/2. In other words, the bandwidth of the PGA 110 at this time is smaller than (i.e., is turned down) that when the gain is 1. Conversely, when the PGA 110 has a high gain (e.g., a gain of at least 8), the buffered signal Vbuff received by the delta sigma ADC 130 has the bandwidth of the buffer 120 since the buffer 120 is enabled. Since the bandwidth of the buffer 120 is larger than the bandwidth of the PGA 110 at high gains, and the buffer 120 does not affect the gain of the PGA 110, it can be regarded as increasing the bandwidth of the PGA 110. Furthermore, when the PGA 110 has a higher gain (e.g., a gain of at least 32), the bandwidth control circuit 150 also adjusts the bias current I of the PGA 110 through the control signal Vpga such that the bandwidth of the PGA 110 increases.

The present invention provides an ADC circuit with controllable PGA bandwidth. Through the bandwidth control circuit, the user can determine the gain and bandwidth of the PGA and enable the gain and bandwidth of the bandwidth control circuit corresponding to the PGA to automatically control the state of the buffer positioned between the PGA and the delta sigma ADC. Due to a low gain, if the PGA can provide an input bandwidth that is no less than that required by the delta sigma ADC, the bandwidth control circuit will disable the buffer automatically. This allows the PGA to directly output the amplified signal to the delta sigma ADC. Thereby reducing power consumption caused by enabling the buffer for a long time and minimizing noise impact on the output signal of the delta sigma ADC. Due to a high gain, if the PGA bandwidth is smaller than the input bandwidth required by the delta sigma ADC, the bandwidth control circuit will automatically enable the buffer. This allows the ADC circuit to have the high gain of PGA while converting to use the buffer to provide the input bandwidth no less than that required by the delta sigma ADC. Thus, it prevents increased noise or complete distortion of the output signal of the delta sigma ADC caused by insufficient sampling time. Furthermore, if the user considers that the bandwidth of the PGA is insufficient for the buffer to operate normally, the bandwidth control circuit can also adjust the current of the PGA appropriately to further increase the bandwidth of the PGA while allowing the PGA to have the high gain.

While the invention has been described by way of example and in terms of the preferred embodiments, it should be understood that the invention is not limited to the disclosed embodiments. Conversely, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An analog-to-digital converter circuit, comprising:
a programmable gain amplifier, configured to receive and amplify an input signal to generate an amplified signal;
a buffer, configured to receive the amplified signal and output a buffered signal correspondingly;
a delta sigma analog-to-digital converter, configured to receive the amplified signal or the buffered signal, and output a digital signal correspondingly; and
a bandwidth control circuit, configured to generate a first control signal and a second control signal, wherein the first control signal is output to the programmable gain amplifier to control a bandwidth of the programmable gain amplifier, and the second control signal is configured to enable or disable the buffer.

2. The analog-to-digital converter circuit as claimed in claim 1, wherein the bandwidth control circuit outputs the first control signal based on a gain of the programmable gain amplifier to control the bandwidth of the programmable gain amplifier.

3. The analog-to-digital converter circuit as claimed in claim 1, wherein the first control signal increases a bias current of the programmable gain amplifier such that the bandwidth of the programmable gain amplifier is increased.

4. The analog-to-digital converter circuit as claimed in claim 1, further comprising:
a switch, having a first end and a second end, wherein the first end is coupled to an input of the buffer, and the second end is coupled to an output of the buffer;
wherein the bandwidth control circuit generates a third control signal to turn on or turn off the switch.

5. The analog-to-digital converter circuit as claimed in claim 4, wherein the bandwidth control circuit outputs the second control signal to disable the buffer and the third control signal to turn on the switch when the bandwidth of the programmable gain amplifier is not less than an input bandwidth required by the delta sigma analog-to- digital converter, such that the programmable gain amplifier outputs the amplified signal to the delta sigma analog-to-digital converter through the switch which is turned on.

6. The analog-to-digital converter circuit as claimed in claim 4, wherein the bandwidth control circuit outputs the second control signal to enable the buffer and the third control signal to turn off the switch when the bandwidth of the programmable gain amplifier is less than an input bandwidth required by the delta sigma analog-to-digital converter, such that the programmable gain amplifier outputs the amplified signal to the buffer, and the buffer outputs the buffered signal to the delta sigma analog-to-digital converter.

7. The analog-to-digital converter circuit as claimed in claim 6, wherein the bandwidth of the programmable gain amplifier is not less than an input bandwidth required by the buffer.

8. The analog-to-digital converter circuit as claimed in claim 6, wherein the bandwidth control circuit outputs the first control signal to the programmable gain amplifier based on a gain of the programmable gain amplifier to control the bandwidth of the programmable gain amplifier.

9. The analog-to-digital converter circuit as claimed in claim 1, wherein the programmable gain amplifier is a double-ended differential amplifier, and the buffer is a unit gain buffer.

10. An analog-to-digital converter circuit, comprising:
a programmable gain amplifier, configured to receive and amplify an input signal to generate an amplified signal;
a buffer, configured to receive the amplified signal and output a buffered signal correspondingly;
a delta sigma analog-to-digital converter, configured to receive the amplified signal or the buffered signal, and output a digital signal correspondingly; and
a bandwidth control circuit, configured to turn down a bandwidth of the programmable gain amplifier when the programmable gain amplifier has a low gain and to turn up the bandwidth of the programmable gain amplifier when the programmable gain amplifier has a high gain.
